(19) United States
(12) Patent Application Publication
(10) Pub. No.: US 2025/0293066 A1
(43) Pub. Date: Sep. 18, 2025

(54) SYSTEMS AND METHODS FOR RECOVERY OF AN IMPAIRED VEHICLE ON A SUSPENDED TRACK

(71) Applicant: Taiwan Semiconductor Manufacturing Company, Ltd., Hsinchu (TW)

(72) Inventors: Ting-Hao Chang, Hsinchu (TW); Chia-hua Lin, Hsinchu (TW); Shinming Kao, Keelung (TW); Tzu-Hsiang Yu, Taoyuan (TW); Ting-Hung Liu, Chiayi (TW)

(73) Assignee: Taiwan Semiconductor Manufacturing Company, Ltd., Hsinchu (TW)

(21) Appl. No.: 18/605,515

(22) Filed: Mar. 14, 2024

(51) Int. Cl. H01L 21/677; B61B 12/02

(52) U.S. Cl. CPC H01L 21/67724; B61B 12/02; H01L 21/67733

(57) ABSTRACT

Systems and methods are provided for recovery of a first vehicle that travels on a suspended track disposed at an elevated position within a facility. The systems include the suspended track, the first vehicle configured to travel along the suspended track, and an emergency wheel assembly configured to replace a first wheel assembly on the first vehicle while the first vehicle remains on the suspended track, the emergency wheel assembly including a wheel configured to freely rotate on an axle of the first vehicle. In some examples, the systems may include a second vehicle configured to travel along the suspended track, a coupling device configured to couple the first vehicle to the second vehicle, and a controller configured to operate the second vehicle to move along the suspended track while coupled to the first vehicle with the coupling device and thereby tow the first vehicle.

### BACKGROUND

A semiconductor Front Opening Unified Pod (FOUP) is a specialized container used in the semiconductor integrated circuit (IC) manufacturing industry to transport and store semiconductor wafers in a clean and controlled environment. The FOUP promotes cleanliness and integrity of the wafers during various stages of the semiconductor manufacturing process. Transportation of the FOUPs may vary depending on the stage of the manufacturing process and/or the layout of the facilities. In some situations, automated material handling systems (AMHS) including overhead conveyance systems may be employed to transport FOUPs. These systems may include automated or remote controlled vehicles that move on suspended tracks along a predefined path. In general, FOUPs are used to minimize human intervention, reduce the risk of contamination, and promote efficient movement of FOUPs between different processing tools.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents automated vehicles transporting semiconductor wafers along suspended tracks between stages in an integrated circuit manufacturing process in accordance with some embodiments;

FIG. 2 is a perspective view of an emergency wheel assembly for promoting movement of a disabled automated vehicle in accordance with some embodiments;

FIG. 3 is an exploded view of certain components of the wheel assembly of FIG. 2 in accordance with some embodiments;

FIG. 4 is a perspective view of a wheel of the wheel assembly of FIG. 3 in accordance with some embodiments;

FIG. 5 is a top view of a coupling device for use while towing a disabled automated vehicle in accordance with some embodiments;

FIG. 6 is a perspective view of a portion of the coupling device of FIG. 5 in accordance with some embodiments;

FIG. 7 is a cross-sectional view of a first attachment member of the coupling device in accordance with some embodiments;

FIG. 8 is a cross-sectional view of an elongated member of the coupling device in accordance with some embodiments; and

FIG. 9 is a flowchart illustrating an exemplary method for moving a disabled automated vehicle in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As will be readily apparent to those skilled in the art upon a complete reading of the disclosure, the structures disclosed herein may be employed with a variety of technologies, and may be incorporated into a variety of industrial and manufacturing.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Automated material handling systems (AMHS) that include overhead conveyance systems (e.g., over hoist transport (OHT) systems) may be employed to transport semiconductor wafers, for example, with Front Opening Unified Pods (FOUPs), FOSBs, trays, cassettes, etc., using automated or remote controlled vehicles (shuttles) that move on suspended tracks along a predefined path within a semiconductor fabrication/manufacturing facility. In the unlikely event that a vehicle moving along the suspended track becomes impaired and unable to move, a recovery procedure must be performed to move the impaired vehicle along the suspended track to allow for repair of the impaired vehicle and/or to allow other vehicles to travel along the suspended track. Such recovery procedures may present a significant challenge due to the elevated position of the impaired vehicle on the suspended track.

Presented herein are embodiments of systems and methods for recovering impaired vehicles that are disabled on a suspended track. For convenience, the systems and methods will be described herein in reference to an overhead conveyance system installed within a semiconductor fabrication facility. However, the systems and methods are not limited to this application and/or to the semiconductor integrated circuit (IC) manufacturing industry. In various embodiments, the systems and methods include replacing motorized wheel assemblies of the impaired vehicle with free-rotating wheel assemblies and then towing the impaired vehicle with another vehicle coupled thereto.

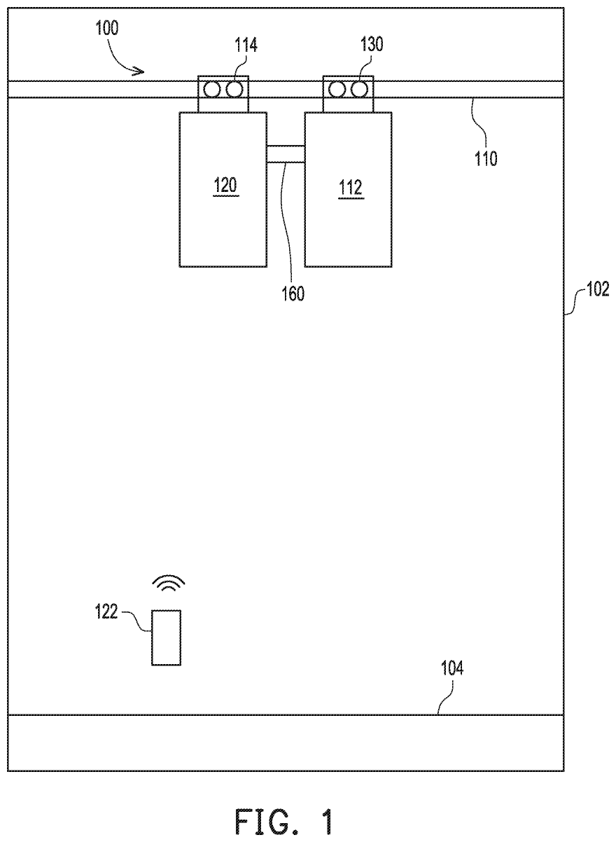

FIG. 1 represents a portion of a semiconductor wafer transportation system 100 within the semiconductor manufacturing facility in accordance with various embodiments. The semiconductor wafer transportation system 100 includes one or more tracks, including a suspended track 110, disposed in an elevated position within the facility, and vehicles configured to travel along the suspended track 110 for various purposes, such as carrying one or more semiconductor wafers (not shown) between various semiconductor processing tools within the facility. The vehicles may be configured to move along the suspended track 110 on wheel assemblies. In some examples, the wheel assemblies may be motorized to provide for self-propulsion of the vehicles. The vehicles may be autonomous, that is, traveling along the suspended track 110 at times, speeds, and between destinations according to preprogramed instructions, or may be initiated, operated, or controlled remotely by an operator. Each of the vehicles may include a controller configured to operate the vehicle to move along the suspended track 110 in accordance with the preprogrammed instructions and/or at the direction of a remote device. The controller may include various electronic devices configured to execute the operation of the vehicle, such as one or more processors, a memory device, and a communication bus. In some examples, the vehicle may include a wireless communication device for remote communication with one or more separate systems or devices.

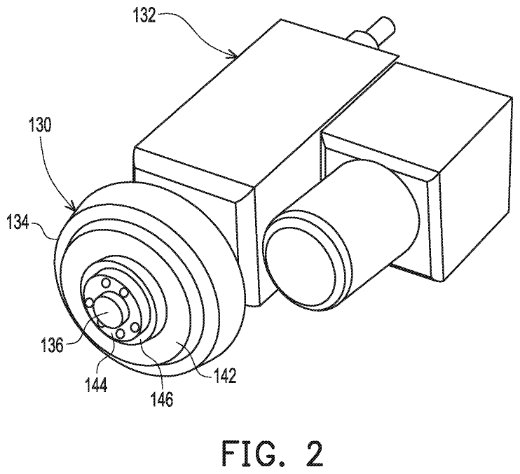

In FIG. 1, a first vehicle 112 and a second vehicle 120 are presented as being coupled to the suspended track 110 for travel thereon. A nonlimiting example of the first vehicle 112 and the second vehicle 120 may be a chain conveyor vehicle, such as a Daifuku Webb chain conveyor CLW-07/0711. The first vehicle 112 and the second vehicle 120 are configured to hang below the suspended track and include motorized wheel assemblies (not shown) configured to roll on top of and along the suspended track 110. In this example, the first vehicle 112 is impaired and is unable to self-propel along the suspended track 110, for example, due to a failed motor. In order to recover the first vehicle 112, the second vehicle 120 has been coupled to the first vehicle 112 with a coupling device 160. In addition, the motorized wheel assemblies of the first vehicle 112 have been replaced with emergency wheel assemblies 130 having wheels 134 (shown in FIG. 2) configured to freely rotate on corresponding axles of the first vehicle 112. An operator is represented as using a remote device 122 to initiate and/or direct the movement of the second vehicle 120 along the suspended track 110. As the second vehicle 120 moves along the suspended track 110, the first vehicle 112 is towed behind the second vehicle 120 due to the coupling device 160. In this manner, the operator may move the first vehicle 112 to a position on the suspended track 110 where repairs to or replacement of the first vehicle 112 may be completed without undue risk to maintenance personnel and/or without blocking of other vehicles on the suspended track 110.

The emergency wheel assembly 130 may have various structures that promote free rolling on the first vehicle 112 along the suspended track 110. For example, FIGS. 2-4 present various aspects of the emergency wheel assembly 130 in accordance with various embodiments. In this example, the first vehicle 112 includes a motor assembly 132 configured to rotate an axle 136 having a first wheel assembly (not shown) thereon. The first wheel assembly is configured to rotate with fixed relation to the axle 136 and thereby propel the first vehicle 112 along the suspended track 110. Referring initially to FIG. 2, the first wheel assembly has been replaced with the emergency wheel assembly 130 which is configured for free-rotation of the wheel 134 on the axle 136. As used herein, the terms free-rotation, freely rotate, and the like indicate that the wheel 134 rotates and rolls along the suspended track 110 in response to a force being applied to the first vehicle 112. That is, the wheel 134 is configured to rotate on the axle 136 without the axle 136 itself rotating.

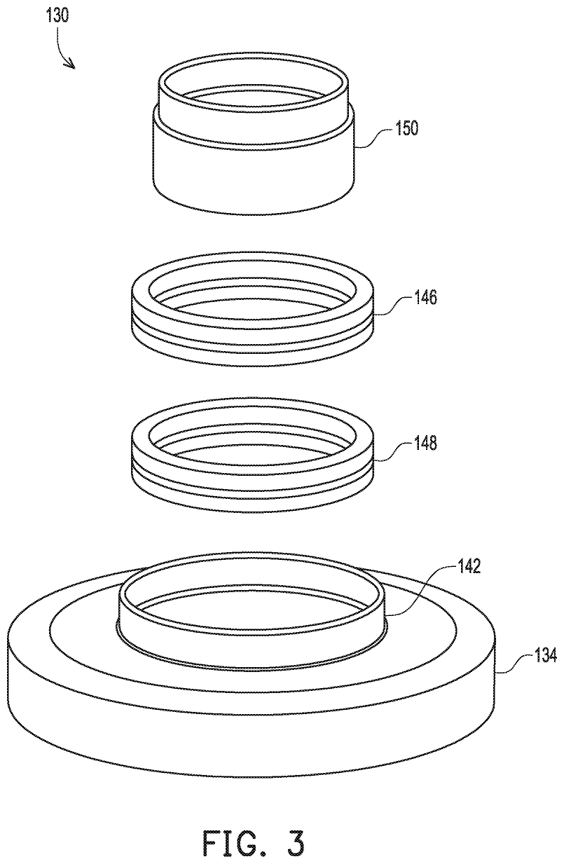

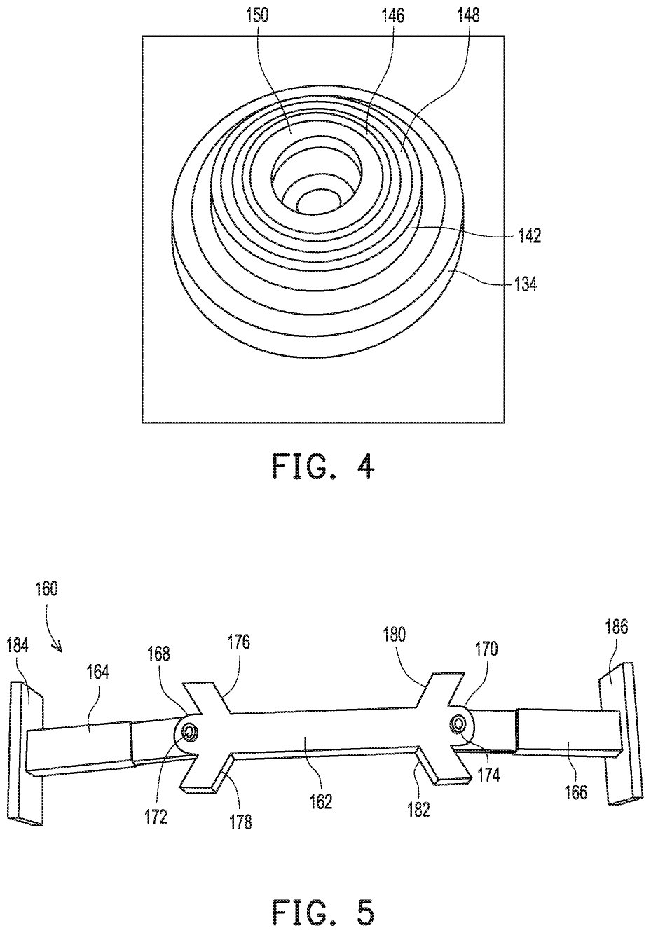

The emergency wheel assembly 130 includes the wheel 134, a hub 142 fixed or secured to the wheel 134, a pair of bearings 146 and 148 configured to allow for the free rotation of the wheel 134 on the axle 136, a spacer 150 configured to be disposed between the pair of bearings 146 and 148 and the axle 136, and a retaining device 144 configured for securing the emergency wheel assembly 130 on the axle 136. FIG. 3 presents an exploded view showing the wheel 134, the hub 142, the pair of bearings 146 and 148 and the spacer 150. FIG. 4 presents a top, perspective view of the wheel 134, the hub 142, the pair of bearings 146 and 148 and the spacer 150 as assembled.

The coupling device 160 may have various structures configured to physically and releasably couple the first vehicle 112 to the second vehicle 120 and maintain the connection therebetween while the second vehicle 120 is towing the first vehicle 112 along the suspended track 110. In some embodiments, the coupling device 160 may have a rigid or semi rigid structure configured to reduce or prevent impact between the first vehicle 112 (i.e., the impaired vehicle) and the second vehicle 120 (i.e., the towing vehicle) during the towing process. The coupling device 160 may include one or more pivoting joints to promote ease of moving about curves in the suspended track 110.

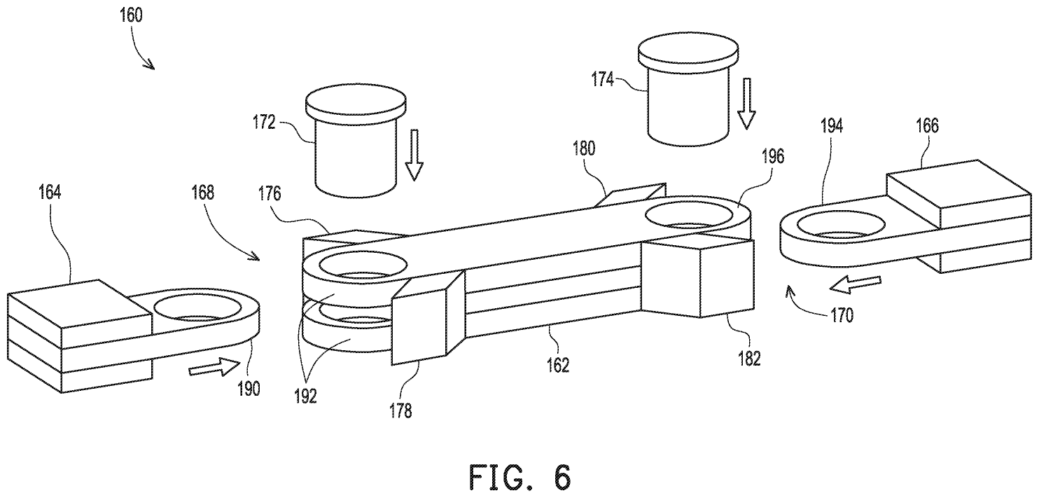

FIGS. 5 and 6 present various aspects of the coupling device 160 in accordance with various embodiments. In this example, the coupling device 160 includes a first attachment member 164 configured to secure to the first vehicle 112, a second attachment member 166 configured to secure to the second vehicle 120, and an elongated member 162 configured to couple at a first end thereof to the first attachment member 164 to define a first pivoting joint 168 and couple at a second end thereof oppositely disposed from the first end to the second attachment member 166 to define a second pivoting joint 170. The first and second pivoting joints 168 and 170 are each configured to allow the elongated member 162 to pivot relative to the first attachment member 164 and/or the second attachment member 166 to promote ease of movement about curves in the suspended track 110. The first attachment member 164, the second attachment member 166, and the elongated member 162 may include or be formed of various materials, including various metallic, polymeric, or composite materials. Specific nonlimiting materials may include various low, medium, and high carbon steels.

The first attachment member 164 and the second attachment member 166 may be releasably or permanently secured to the first vehicle 112 and the second vehicle 120, respectively, with various structures which may be adapted to the specific structure of the first vehicle 112 and the second vehicle 120. In this example, the first attachment member 164 and the second attachment member 166 include first and second mounting plates 184 and 186, respectively, that are configured to be disposed in contact with the first vehicle 112 and the second vehicle 120, respectively, and secured thereto with fasteners (e.g., bolts).

As illustrated in FIG. 6, the first and second pivoting joints 168 and 170 may include interdigitated portions of the ends of the elongated member 162, the first attachment member 164, and the second attachment member 166. In this example, the first attachment member 164 includes a rounded first portion 190 configured to be disposed in a first slot defined between rounded second and third portions 192 at the first end of the elongated member 162 such that holes therethrough are axially aligned. Similarly, the second attachment member 166 includes a rounded fourth portion 194 configured to be disposed in a second slot defined between rounded fifth and sixth portions 196 at the second end of the elongated member 162 such that holes therethrough are axially aligned. The first end of the elongated member 162 is releasably coupled to the first attachment member 164 at the first pivoting joint 168 with a first pin 172 disposed within the holes thereof and the second end of the elongated member 162 is releasably coupled to the second attachment member 166 at the second pivoting joint 170 with a second pin 174 disposed within the holes thereof. In some examples, the first pin 172 and the second pin 174 may include or be formed of various materials, such as various metallic, polymeric, and composite materials, such as steel or aluminum.

The first attachment member 164, the second attachment member 166, and the elongated member 162 each have rigid bodies/structures configured to reduce or prevent impact between the first vehicle 112 and the second vehicle 120 during the towing process. In addition, the elongated member 162 includes a first pair of anti-oversteering members 176 and 178 adjacent the first end thereof and a second pair of anti-oversteering members 180 and 182 adjacent the second end thereof. The anti-oversteering members 176, 178, 180, and 182 protrude outward from sides of the elongated member 162 and are configured to function as physical barriers to limit pivoting between the first and second attachment members 164 and 166 and the elongated member 162 and thereby limit angles therebetween during pivoting of the first and second pivoting joints 168 and 170. By limiting the angles between the first and second attachment members 164 and 166 and the elongated member 162, a likelihood of impact between the first vehicle 112 and the second vehicle 120 is further reduced or prevented during the towing process. In some embodiments, the angles between the first and second attachment members 164 and 166 and the elongated member 162 may be limited to 90 degrees or less, such as 80 degrees or less, such as 70 degrees or less, such as 60 degrees or less, such as 50 degrees or less, such as 45 degrees or less, such as 45 to 90 degrees. In some embodiments, angles greater than, for example, 90 degrees may allow for contact between the first vehicle 112 and the second vehicle 120 during towing of the first vehicle 112.

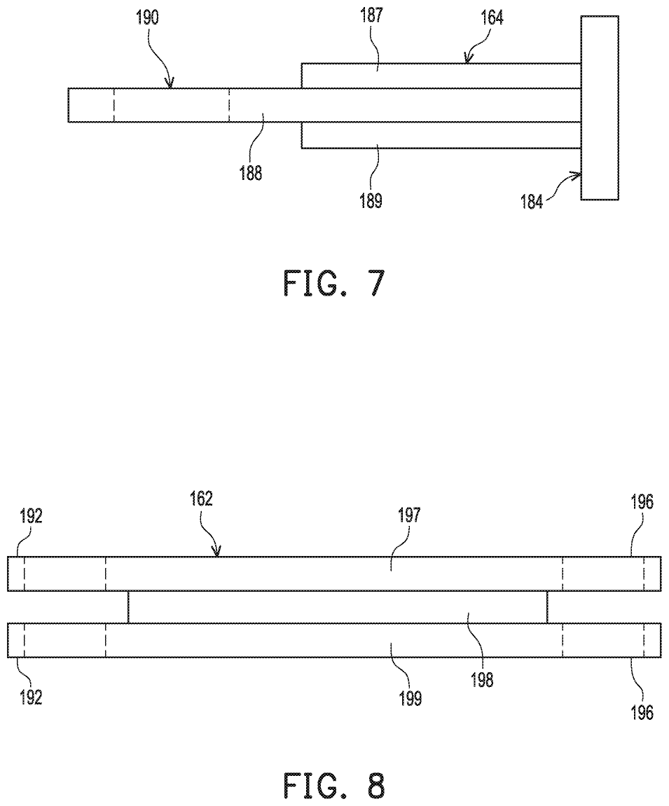

The first attachment member 164, the second attachment member 166, and the elongated member 162 may include various structural configurations. In some examples, the first attachment member 164, the second attachment member 166, and the elongated member 162 have bodies/structures that are formed of stacked layers. For example, FIGS. 7 and 8 include cross-section views illustrating nonlimiting examples of the first attachment member 164 and the elongated member 162, respectively, having stacked layer structures. FIG. 7 presents the first attachment member 164 as including outer layers defined by oppositely disposed first and second members 187 and 189, and an inner layer defined by a third member 189. In this example, the third member 189 has a longer longitudinal dimension than the first and second members 187 and 189 to provide for the rounded first portion 190 at a distal end thereof. In various examples, the first, second, and third members 187, 188, and 189 of the first attachment member 164 may have the same or different cross-sectional thicknesses and may have various longitudinal lengths. Although not shown, the second attachment member 166 may have a similar structure to the example of the first attachment member 164 of FIG. 7. FIG. 8 presents the elongated member 162 as including outer layers defined by oppositely disposed first and second members 197 and 199, and an inner layer defined by a third member 198. In this example, the first and second members 197 and 199 have longer longitudinal dimensions than the third members 198 to provide for the rounded second and third portions 192 at first distal ends thereof and for the rounded fifth and sixth portions 196 at second distal ends thereof. In various examples, the first, second, and third members 197, 198, and 199 of the elongated member 162 may have the same or different cross-sectional thicknesses and various longitudinal lengths.

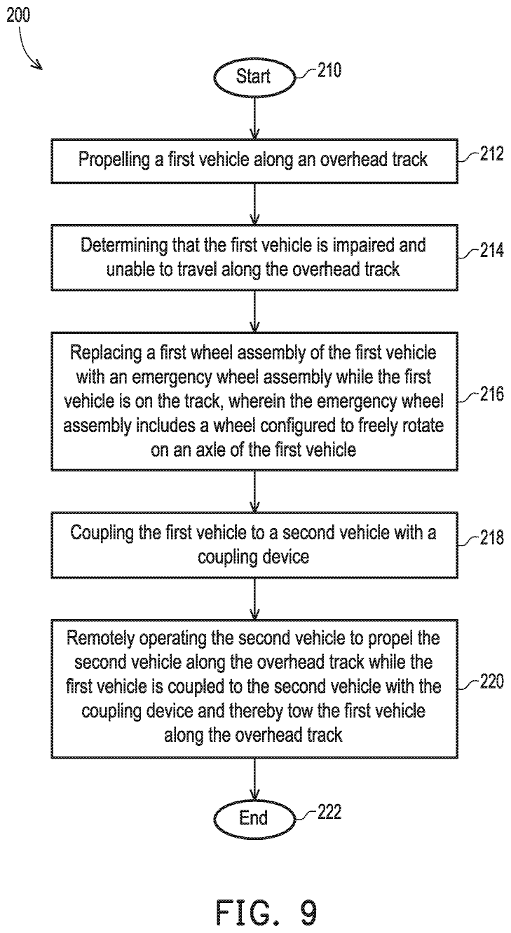

Referring to FIG. 9, an exemplary method 200 is presented for recovering an impaired vehicle on a suspended track. In some embodiments, the method 200 may be used to recover an impaired vehicle from the suspended track 110 of the semiconductor wafer transportation system 100 of FIG. 1. The method 200 may start at 210.

At 212, the method 200 includes propelling a first vehicle (e.g., the first vehicle 112) along a suspended track disposed at an elevated position within a facility. In some embodiments, the first vehicle may be propelled by an onboard motor in accordance with preprogrammed instructions or instructions received wirelessly from a remote system.

At 214, the method 200 includes determining that the first vehicle is impaired and unable to travel along the suspended track. In some embodiments, the determination that the first vehicle is impaired may be based on feedback received from the first vehicle such as computing errors or sensor signals (e.g., motion sensors, positions sensors, etc.). In some embodiments, the determination that the first vehicle is impaired may be based on feedback from systems that are separate from the first vehicle (e.g., cameras, motion detectors, etc.). In some embodiments, determination that the first vehicle is impaired may be determined by personnel of the facility, such as by visual confirmation.

At 216, the method 200 includes replacing a first wheel assembly of the first vehicle with an emergency wheel assembly (e.g., the emergency wheel assembly 130) while the first vehicle is on the suspended track. The emergency wheel assembly includes a wheel configured to freely rotate on an axle of the first vehicle. In some embodiments, replacement of the wheel assembly is performed at an elevated position by personnel of the facility. In some embodiments, the first vehicle includes more than one first wheel assembly, and the method 200 include replacing each of the first wheel assemblies with a corresponding emergency wheel assembly. In some embodiments, the emergency wheel assembly is provided by modifying the first wheel assembly. For example, the first wheel assembly may be removed, the first wheel assembly may be modified such that a wheel thereof is able to freely rotate on an axle thereof. For example, the first wheel assembly may be modified to include one or more bearings.

At 218, the method 200 includes coupling the first vehicle to a second vehicle with a coupling device (e.g., the coupling device 160). In some embodiments, coupling the first vehicle to the second vehicle may include releasably coupling a first end of an elongated member of the coupling device to a first attachment member of the first vehicle with a first pin to define a first pivoting joint, and releasably coupling a second end of the elongated member of the coupling device oppositely disposed the first end to a second attachment member of the second vehicle with a second pin to define a second pivoting joint. In some embodiments, the method 200 may include propelling the second vehicle along the suspended track to be adjacent to the first vehicle prior to coupling the first vehicle to the second vehicle with the coupling device.

At 220, the method 200 includes propelling the second vehicle along the suspended track while the first vehicle is coupled to the second vehicle with the coupling device and thereby tow the first vehicle along the suspended track. In some embodiments, the second vehicle may be propelled by an onboard motor in accordance with preprogrammed instructions or instructions received from a remote system. In some embodiments, the method 200 may include rotating the wheel about the axle of the first vehicle with a bearing of the emergency wheel assembly while the second vehicle is towing the first vehicle.

In some embodiments, the method 200 may include propelling the second vehicle about a curve in the suspended track while the first vehicle is coupled to the second vehicle. In some embodiments, movement about the curve in the suspended track causes pivoting of a first pivoting joint of the coupling device. In some embodiments, movement about the curve in the suspended track causes pivoting of a second pivoting joint of the coupling device.

In some embodiments, the coupling device includes a first pivoting joint coupling first and second members of the coupling device. In such embodiments, the method 200 may include limiting pivoting of the first pivoting joint with an anti-oversteering member of the coupling device and thereby limiting an angle between the first and second members during pivoting of the first pivoting joint.

In some embodiments, the facility is a semiconductor manufacturing facility and the method 200 may include propelling the first vehicle along the suspended track while carrying a semiconductor wafer therein.

The method 200 may end at 222.

The present disclosure therefore provides systems and methods for methods for recovering impaired vehicles that are disabled on a suspended track that may significantly reduce risk of injury to facility personnel and reduce operating costs of the facility.

In accordance with an embodiment, a semiconductor wafer transportation system is provided that includes a suspended track disposed in an elevated position within a semiconductor manufacturing facility, a first vehicle configured to travel along the suspended track while carrying a semiconductor wafer, and an emergency wheel assembly configured to replace a first wheel assembly on the first vehicle while the first vehicle remains on the suspended track, the emergency wheel assembly including a wheel configured to freely rotate on an axle of the first vehicle.

In accordance with another embodiment, a method is provided that includes propelling a first vehicle on a first wheel assembly thereof along a suspended track disposed at an elevated position within a semiconductor manufacturing facility, wherein the first vehicle is carrying a semiconductor wafer therein, determining that the first vehicle is impaired and unable to travel along the suspended track, replacing the first wheel assembly with an emergency wheel assembly while the first vehicle is on the suspended track, wherein the emergency wheel assembly includes a wheel configured to freely rotate on an axle of the first vehicle, and moving the first vehicle along the suspended track on the emergency wheel assembly.

In accordance with yet another embodiment, a method is provided that includes propelling a first vehicle on a first wheel assembly thereof along a suspended track disposed at an elevated position within a semiconductor manufacturing facility, wherein the first vehicle is configured to carry a semiconductor wafer therein, determining that the first vehicle is impaired and unable to travel along the suspended track, coupling the first vehicle to a second vehicle with a coupling device, and remotely operating the second vehicle to propel the second vehicle along the suspended track while the first vehicle is coupled to the second vehicle with the coupling device and thereby tow the first vehicle along the suspended track.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor wafer transportation system, comprising:
a suspended track disposed in an elevated position within a semiconductor manufacturing facility;
a first vehicle configured to travel along the suspended track while carrying a semiconductor wafer; and
an emergency wheel assembly configured to replace a first wheel assembly on the first vehicle while the first vehicle remains on the suspended track, the emergency wheel assembly including a wheel configured to freely rotate on an axle of the first vehicle.

2. The semiconductor wafer transportation system of claim 1, further comprising:
a second vehicle configured to travel along the suspended track;
a coupling device configured to physically and releasably couple the first vehicle to the second vehicle and maintain a connection therebetween while the second vehicle is towing the first vehicle along the suspended track; and
a controller configured to operate the second vehicle to move along the suspended track while coupled to the first vehicle with the coupling device and thereby tow the first vehicle.

3. The semiconductor wafer transportation system of claim 2, wherein the coupling device includes:
a first attachment member configured to secure to the first vehicle;
a second attachment member configured to secure to the second vehicle; and
at least two pivoting joints disposed between the first attachment member and the second attachment member each configured to pivot relative to the first attachment member or the second attachment member.

4. The semiconductor wafer transportation system of claim 3, wherein the coupling device includes an elongated member configured to couple at a first end thereof to the first attachment member to define a first pivoting joint of the at least two pivoting joints and couple at a second end thereof oppositely disposed from the first end to the second attachment member to define a second pivoting joint of the at least two pivoting joints.

5. The semiconductor wafer transportation system of claim 4, wherein the first end of the elongated member is releasably coupled to the first attachment member at the first pivoting joint with a first pin and the second end of the elongated member is releasably coupled to the second attachment member at the second pivoting joint with a second pin.

6. The semiconductor wafer transportation system of claim 2, wherein the coupling device includes first and second members, a pivoting joint coupling the first and second members, and an anti-oversteering member configured to limit pivoting of the pivoting joint while towing the first vehicle with the second vehicle and thereby limit an angle between the first and second members.

7. The semiconductor wafer transportation system of claim 1, wherein the emergency wheel assembly includes a bearing configured to provide for free rotation of the wheel about the axle.

8. A method, comprising:
propelling a first vehicle on a first wheel assembly thereof along a suspended track disposed at an elevated position within a semiconductor manufacturing facility, wherein the first vehicle is carrying a semiconductor wafer therein;
determining that the first vehicle is impaired and unable to travel along the suspended track;
replacing the first wheel assembly with an emergency wheel assembly while the first vehicle is on the suspended track, wherein the emergency wheel assembly includes a wheel configured to freely rotate on an axle of the first vehicle; and
moving the first vehicle along the suspended track on the emergency wheel assembly.

9. The method of claim 8, further comprising:
coupling the first vehicle to a second vehicle with a coupling device; and
remotely operating the second vehicle to propel the second vehicle along the suspended track while the first vehicle is coupled to the second vehicle with the coupling device and thereby tow the first vehicle along the suspended track on the emergency wheel assembly.

10. The method of claim 9, further comprising propelling the second vehicle about a curve in the suspended track while the first vehicle is coupled to the second vehicle, wherein movement about the curve in the suspended track causes pivoting of a first pivoting joint of the coupling device.

11. The method of claim 10, wherein the movement about the curve in the suspended track causes pivoting of a second pivoting joint of the coupling device.

12. The method of claim 9, wherein a first pivoting joint couples first and second members of the coupling device, and the method includes limiting pivoting about the first pivoting joint with an anti-oversteering member of the coupling device while towing the first vehicle with the second vehicle to thereby limit an angle between the first and second members.

13. The method of claim 9, wherein coupling the first vehicle to the second vehicle with the coupling device includes:
releasably coupling a first end of an elongated member of the coupling device to a first attachment member of the first vehicle with a first pin to define a first pivoting joint; and
releasably coupling a second end of the elongated member of the coupling device oppositely disposed the first end to a second attachment member of the second vehicle with a second pin to define a second pivoting joint.

14. The method of claim 9, further comprising propelling the second vehicle along the suspended track to be adjacent to the first vehicle prior to coupling the first vehicle to the second vehicle with the coupling device.

15. A method, comprising:
propelling a first vehicle on a first wheel assembly thereof along a suspended track disposed at an elevated position within a semiconductor manufacturing facility, wherein the first vehicle is configured to carry a semiconductor wafer therein;
determining that the first vehicle is impaired and unable to travel along the suspended track;
coupling the first vehicle to a second vehicle with a coupling device; and
remotely operating the second vehicle to propel the second vehicle along the suspended track while the first vehicle is coupled to the second vehicle with the coupling device and thereby tow the first vehicle along the suspended track.

16. The method of claim 15, further comprising replacing the first wheel assembly with an emergency wheel assembly while the first vehicle is on the suspended track, wherein the emergency wheel assembly includes a wheel configured to freely rotate on an axle of the first vehicle.

17. The method of claim 15, further comprising propelling the second vehicle about a curve in the suspended track while the first vehicle is coupled to the second vehicle, wherein movement about the curve in the suspended track causes pivoting of a first pivoting joint of the coupling device.

18. The method of claim 17, wherein the movement about the curve in the suspended track causes pivoting of a second pivoting joint of the coupling device.

19. The method of claim 15, wherein a first pivoting joint couples first and second members of the coupling device, and the method includes limiting pivoting about the first pivoting joint with an anti-oversteering member of the coupling device while towing the first vehicle with the second vehicle to thereby limit an angle between the first and second members.

20. The method of claim 15, wherein coupling the first vehicle to the second vehicle with the coupling device includes:
releasably coupling a first end of an elongated member of the coupling device to a first attachment member of the first vehicle with a first pin to define a first pivoting joint; and
releasably coupling a second end of the elongated member of the coupling device oppositely disposed the first end to a second attachment member of the second vehicle with a second pin to define a second pivoting joint.
